(19) United States
(12) Patent Application Publication
(10) Pub. No.: US 2024/0427963 A1
(43) Pub. Date: Dec. 26, 2024

(54) Device and Method for Simulating the Operating Behavior of a Scale, in Particular a Combination Scale, by Means of a Digital Model and Numerical Simulation

(71) Applicant: MULTIPOND Wägetechnik GmbH, Waldkraiburg (DE)

(72) Inventors: Julia HARTMANN, Augsburg (DE); Andreas PETERS, Aschau am Inn (DE); Felix PROFE, Winhöring (DE); Markus SPATENEDER, Pleiskirchen (DE); Stanislav JOCHIM, Heldenstein (DE); Jurij VILISOV, Waldkraiburg (DE); Felix WALDHöR, Reut (DE); Wolfram ZECK, Mühldorf (DE)

(21) Appl. No.: 18/754,755

(22) Filed: Jun. 26, 2024

(30) Foreign Application Priority Data
Jun. 26, 2023 (DE) 20 2023 103 530.2

(51) Int. Cl. G06F 30/23

(52) U.S. Cl. CPC G06F 30/23

(57) ABSTRACT

The present invention is concerned with a simulation of the operation of a scale, in particular a combination scale, with the aid of a digital model of a scale, in particular a combination scale, with the aid of a digital model of a scale and its sub-components as well as a numerical simulation, in particular a product simulation. For this purpose, a digital model of the scale is created, and a product simulation of an operation of a scale is carried out. Then, the control data set of the scale is optimized.

### CROSS-REFERENCE TO RELATED APPLICATIONS

This application claims priority to German Patent Application No. 20 2023 103 530.2, which was filed on Jun. 26, 2023 and entitled VORRICHTUNG ZUR SIMULATION DES BETRIEBSVERHALTENS EINER WAAGE, INSBESONDERE KOMBINATIONSWAAGE, MITTELS EINES DIGITALEN MODELLS UND DEM-SIMULATION, the entire contents of which is hereby incorporated by reference.

### FIELD OF THE INVENTION

The present invention deals with a simulation of the operation of a scale, in particular a combination scale, with the aid of a digital model of a scale and its sub-components as well as a numerical simulation, in particular a product simulation. Furthermore, the present invention is directed to a simulation device with which the operating behavior of a scale, in particular a combination scale, as well as the conveying devices connected thereto can be simulated. Thus, control parameters for a scale be selected, adapted and optimized dependent on respective product properties.

The numerical simulation can be, for example, a DEM simulation (Discrete Element Methods Simulation), FEM simulation (Finite Element Methods Simulation), MKS (Multi-Body Simulation). The numerical simulation can be combined with learnable methods for dynamic processes and time series, e.g. a nonlinear autoregressive exogenous model (NARX), long short-term memory (LSTM), reinforcement learning (RL) and/or iterative learning control (ILC).

### BACKGROUND

In the prior art, a combination scale is known from document EP 1 166 057 B1. Here, products are conveyed from a distribution device by feeding, before they fall into corresponding storage containers or then into corresponding weighing containers. Subsequently, products are collected by a collecting device. The frames are in particular important for corresponding storage or weighing containers, i.e. the base bodies of the corresponding storage or weighing containers, since these collect the products to be weighed and—when used as weighing containers—the weighing process is also carried out in these.

Furthermore, a partial quantity combination scale is known from document DE 44 04 897 A1. This serves to create a total weight quantity from different partial quantities, with vibrating conveyor channels, preliminary containers connected downstream of the vibrating conveyor channels, an arbitrary number of individual scales with weighing containers which are connected downstream of the preliminary containers, storage containers for intermediate storage of partial quantities already considered and registered in a common control and monitoring device, and a collecting device.

In the case of a combination scale, comprehensive tests must always be carried out, in particular in the food industry and food-processing industry, as to whether a specific scale is suitable for the handling of specific products, and it must subsequently be determined how corresponding control parameters must be selected. Frequent problems in combination scales are, for example, product jams in parts of the scale, in particular clumps of products, product accumulations or other disturbances. This can happen in particular in the case of sticky products, such as, for example, in the case of chewy candies, gum bears, pieces of meat or other products. Elongated products can also cause problems if they become wedged, for example, in parts of the scale. This is the case, for example, for chocolate bars or packs of chewy candies. During the configuration and during the production of such a scale, comprehensive tests must therefore be carried out for the products which are to be weighed later with such a scale, so that the most suitable scale and scale configuration on the one hand and the most suitable operating parameters on the other hand can be found with the aim that the scale can operate optimally and without disturbances for a specific application. Such a selection of a scale on the one hand and the corresponding setting and the selection of control parameters on the other hand mean increased work complexity and thus high costs.

It is therefore an object of the present invention to provide a method and a device which make it possible to adapt a control of a scale to specific product quickly and as cost-effectively as possible.

### SUMMARY OF THE INVENTION

This object is achieved by a method for configuring a scale, according to claim 1 and a simulation device according to claim 9. Further advantageous embodiments of the present invention are the subject matter of the dependent claims.

A method according to the invention for configuring a scale, in particular combination scale, comprises the following steps: a) providing a digital model of a basic configuration of the scale and an initial control data set of the scale; b) providing data of the products to be transported; c) numerical simulation of the movement of products over the transport path of the scale; d) adapting and/or optimizing the control data set of the scale, based on results of the numerical simulation; and e) outputting the adapted and/or optimized control data set of the scale.

A simulation device according to the invention comprises: an input device which is adapted to read in a digital model of a basic configuration of the scale, an initial control data set of the scale and data of the products to be transported; a computing unit which is adapted to simulate the behavior of a product to be transported as a function of the initial control data set with the aid of numerical simulation, and to carry out adaptations and/or optimizations of the control data set of (and optionally of the digital model) of the scale; an output device which is adapted to output a control data set (and optionally a digital model) (which has/have been adapted and/or optimized).

Exemplary embodiments of the present invention are described in more detail below by the accompanying figures.

### BRIEF DESCRIPTION OF THE DRAWINGS

FIG. 1 shows a flowchart of a process in which a scale is configured on the basis of customer wishes.

FIG. 2 shows, by way of example, a flowchart of a process in which the product feed to the storage containers can be regulated in a manner adapted to simulation results.

FIG. 3 shows a schematic view of a combination scale.

FIG. 4 shows the transport path of the product over individual parts of the scale more precisely.

FIG. 5 shows a schematic view of a simulation device.

Before any embodiments of the invention are explained in detail, it is to be understood that the invention is not limited in its application to the details of construction and the arrangement of components set forth in the following description or illustrated in the following drawings. The invention is capable of other embodiments and of being practiced or of being carried out in various ways. Also, it is to be understood that the phraseology and terminology used herein is for the purpose of description and should not be regarded as limiting.

### DETAILED DESCRIPTION

A method according to the invention for configuring a scale, in particular combination scale, comprises the following steps:
a) providing a digital model of a basic configuration of the scale and an initial control data set of the scale;
b) providing data of the products to be transported;
c) numerical simulation of the movement of products over the transport path of the scale;
d) adapting and/or optimizing the control data set of the scale, based on results of the numerical simulation;
e) outputting the adapted and/or optimized control data set of the scale.

In step a), a digital model of a suitable scale can be provided, for example on the basis of customer wishes. It can play a role here how many cycles per minute are to be realized, what the nominal filling weight is, what accuracies are required in the scale, how much space is available for the scale (in particular what height), what hygiene regulations apply, what the regulatory requirements and environmental conditions are, as the return of investment should be, etc. Furthermore, it plays a role which product throughput of the scale is required, i.e. how many products can be safely weighed per unit of time. In the design, it can be important that the entire scale or assemblies thereof are designed on the basis of demands on the service life. Relevant measurement variables have to be identified for the maintenance of the scale. The digital model comprises predominantly geometric dimensions of the scale and of the scale parts. The initial control data set comprises, for example, vibration frequencies and vibration amplitudes of parts of the scale which transport product.

However, the digital model can also include a physical model (white box: equations), neural network (black box) or hybrid model (grey box).

In step b), product data are provided—these can be geometric dimensions, but also piece weight, surface properties, coefficients of friction, etc. of the product.

Furthermore, the following parameters can belong to the product data: the product volume, the specific shape ratio, the orientation in space, the intrinsic movement (rotation, rolling friction, center of mass, inertia parameters, etc.), the density, the bulk density, the bulk weight, the piece weight, the elasticity, the deformability, the modulus of elasticity, the transverse contraction number, the hardness, the static friction, the sliding friction, the abrasion properties, the surface roughness, the magnetic properties, the electrical properties, the thermal properties such as thermal conductivity and melting point, the product price, the toxicity, the dust explosion class, etc.

In step c), a numerical simulation of the movement of products over the transport path of the scale is carried out (i.e. a product behavior simulation)—in this case a specific number of products is used for the simulation. Thus, it can be established whether the movement of the products proceeds homogeneously, or whether possibly product jams, wedges or other disturbances occur which could negatively influence the product throughput of the scale.

In this case, the behavior of the product on various surfaces and under various conditions can be simulated on the basis of typical parameters (size, friction, structure, etc.), such as, for example, the flow behavior on charging devices, distribution devices, metering channels, chutes, funnels, discharge plates, and the positioning of the product within containers, guide devices, etc.

Thus, the maximum number of products which can be counted reliably by weighing can also be determined on the basis of numerical simulation. Also here, an optimization can be carried out, i.e. a higher throughput can be achieved by changing the control data set of the scale or scale parts.

In step d), the control data ser of the scale is correspondingly adapted or optimized—the control or the scale or of scale parts is hence changed.

Optionally, a calculation/change of the design dimensions of assemblies of the scale can also be carried out on the basis of the behavior of the digital model of the scale and the numerical simulation—thus, for example, the shape of a charging device, of a distribution plate, of metering channels, storage containers, weighing containers, collecting containers, chutes, funnels and other parts of the product guide (e.g. stoppers, discharge plates, baffles) can be calculated and optimized.

In addition, higher vibration amplitudes can be set in the control data set or control and regulating data set or the for individual parts of the scale, such as, for example, the distribution plate. A multiplicity of changes can be carried out here, and the numerical simulation can be repeated for all combinations of changes until an optimal state is found.

Steps c) and d) can therefore be repeated as often as desired.

In step e), the optimized control data ser of the scale is output. This can now be used for a real scale.

The focus of the present invention is on the optimization of the control data set of the scale.

Preferably, the method further comprises the following step:
f) reading the control data set generated in step e) into a control device of the scale.

This provides an adaptive, optimized control for the scale, and the effects of changes to the control strategies and control parameters are qualified on the digital model. After validation, the model is then transferred to the real control system.

Thus, a scale can be configured, and operation can be started on a real scale (for example during installation or during removal) without extensive preliminary experiments, merely with a simulated control data set. Parameters of the control can be adapted with the numerical simulation for the desired product distribution; a quasi-real mode is hence operated here. Furthermore, initial parameters of the quasi-real operation can be recorded; a later comparison in the real operation of the scale then makes it possible to detect any deviations and thus to adapt the parameters of the digital model and the numerical simulation.

New assemblies can also be added on the basis of the coupling of numerical simulation and optimization of a control data set in the operation of a real scale; for example, a pivoting funnel unit of a transfer system for the scale can be newly adapted here. Fluctuations can be generated by the numerical simulation and the effect on the new assembly can be tested, and necessary parameters for the operation of the new assembly, such as, for example, the transfer system, can be determined therefrom.

This relates, for example, to the dwell time and the pivoting time of a pivoting funnel of a product transfer system.

Optionally, in step a), the basic configuration of the scale is the geometric dimensions of the scale or parts of the scale, and/or the surface properties of the scale or parts of the scale. The geometric dimensions of all the components of the scale can thus be stored here, for example with the aid of a CAD file, and the surface properties, such as, for example, coefficients of sliding friction and coefficients of static friction, can also be correspondingly stored. Furthermore, environmental properties of the scale, such as, for example, temperature, air pressure, can be stored.

Thus, for example, the product behavior of sticky products can be tested extensively without a complex experiment having to be carried out here with a relatively large amount of sticky product. Also, for example, moduli of elasticity of the products can be stored, such as, for example, in the case of lettuce leaves, etc. Also, permissible stresses can be stored which can be present in the product without the latter tearing or breaking—for example in the case of deep-frozen fries, croissants, biscuits, etc.

Optionally, the basic configuration of the scale can include environmental properties of the scale, such as, for example, the temperature or the humidity, vibrations or speeds of wind, drafts, etc. Thus, in a certain range, it is also possible to simulate other environmental conditions which can occur later during operation of the scale, such as, for example, as a result of increased solar radiation, the occurrence of clouds, shading of the scale, wind as a result of the opening of hall doors, operation of a fan or the passage of large means of transport. Vibrations or vibrations of other system parts (steep conveyors, conveyor belts, presses, pelleting systems, etc.) can also play a role.

Thus, with the aid of the simulation, the effect of changes in the environmental factors on the internal control parameters can be correspondingly calculated. In this way, it is also possible to examine the product behavior, such as, for example, the change in the product properties in the case of solar radiation of deep-frozen fries, chocolate bars or other foodstuffs.

Thus, without complex experiments, it is possible to test a plurality of operating conditions which could occur in the later operation of the scale. Adapted control parameters could then also be stored for these operating conditions.

The temperature as a parameter is dependent, for example, on: solar radiation from a certain time, solar radiation in the case of disappearance of clouds, solar radiation only on one side, shading by further, movable system parts.

Preferably, the transport path of the scale comprises a charging device and/or a distribution plate and/or at least one metering channel and/or at least one storage container and/or at least one weighing container and/or at least one chute and/or a funnel and/or at least one collecting container and/or a product guiding device. These are all components with geometric properties which can be correspondingly stored in the digital model. Surface properties of the individual components can also differ. Optionally, the transport path of the scale can also comprise stoppers and/or diverter plates. Within the numerical simulation, geometric properties, surface properties etc. of these components can also be correspondingly changed, and it is possible to check what effect the changes can have on the product flow. Thus, individual parts of the scale can be optimized.

Preferably, a charging device has a charging device drive, a distribution plate has a distribution plate drive, a metering channel has a metering drive and a product guiding device has a product guiding device drive. Further preferably, a storage container has at least one storage container flap, a weighing container has at least one weighing container flap, and a collecting container has at least one collecting container flap. Corresponding operating parameters of these parts are comprised in the control data set. All parts can also be present multiple times. Of course, even more drives can also be present, for example for flaps.

Optionally, in step c), bore tolerances, length tolerances and/or position tolerances) are taken into account in the simulation. This means that all combinations of displacements of the components (for example two components which are connected to a screw and bores) are simulated, and it is possible to check whether events which could disrupt the product flow can arise in this way. Thus, the behavior of the digital model can be tested if all tolerance fluctuations move within the permitted limits. It is also possible to check whether vibrations or resonances could arise in certain operating situations in this way. Also, for example, the influence of tolerances of electrical components (MOSFETs, diodes, contact resistances, etc.) could be simulated and an increased power loss and a reduction in the service life can thus be established. It is also possible in this way to establish whether local overheating could occur which could damage sensitive scale parts or products. Internally occurring or external resonances and/or vibrations in certain operating situations can also be taken into account.

In step b), preferably characteristic product properties, preferably geometric dimensions of products and/or surface properties of products and/or friction properties of products are provided. As a result, it is possible to characterize a product with a plurality of parameters which are important for the transport behavior of the product. Elastic properties of the products could also play a role here, i.e. whether a specific product can be crushed without being damaged or destroyed in the process.

Preferably, in step d), the control data set of the scale, optionally also the basic configuration of the scale, can be optimized based on simulated product behavior, preferably simulated product speed, simulated homogeneity of the product flow and/or the simulated probability of the occurrence of product jam. This means that the control data set of the scale, optionally also geometries of parts of the scale, are correspondingly changed, and it is then checked what effects certain changes can have on a product speed, the homogeneity of the product flow or the probability of the occurrence of product jam. Thus, it can be ensured that the scale is operated with simulated parameters in which the possibility of the occurrence of a product jam is minimized.

Here, for example, criteria can be defined which must be complied with, such as, for example, the disturbance-free operation of a scale (i.e. without product jam) for a specific time period.

The control data set of the scale preferably comprises at least one of the following parameters:
vibration amplitude of the distributor plate drive
vibration frequency of the distributor plate drive
rotational speed of the distributor plate drive
vibration amplitude of at least one metering channel drive
vibration frequency of at least one metering channel drive
opening time and opening duration of the at least one storage container flap
opening time and opening duration of the at least one weighing container flap
opening time and opening duration of the at least one collecting container flap
movement sequences of a product guiding device.

Of course, even more parameters can also be comprised, for example vibration amplitude and vibration frequency of the charging device, the duration of rotation and direction of rotation of the distribution plate, and also metering times of the containers. The movement profile of individual scale parts can also be preserved (i.e. the temporal sequence of movements, i.e., for example, first slow movement of the distribution plate, then faster movement . . . ).

Thus, there are sufficient possibilities for changing the scale control in order thus to establish with the simulation whether the probability of product jams can be increased or reduced.

An arbitrary number of parameter combinations can be simulated, and the behavior of the scale can thus be examined.

Preferably, in step c), N products are used for the simulation (N is an integer greater than 1). The number of products can be selected to be as high as possible in order here to simulate a behavior which is as robust as possible.

Examples of the influences of these parameters are as follows:

The vibration amplitude of the metering channel, the metering time and the opening time of the containers can be used for the calculation of the conveyability of specific products on the basis of the numerical simulation. Furthermore, the effects of changes in control strategies and parameters can be validated on the digital model, and then transferred into the real controller.

A product behavior on specific scale parts can also be tested, for example on a charging unit and a particularly shaped distribution plate (e.g. folded distribution plate). Here, the effects of different fillings on the ability of the products to orient themselves can be examined (for example, elongated products along the “folding troughs” of the folded distribution plate can then fall correctly onto the metering channel or not). Furthermore, for example, the rotational speed of a distribution plate can be regulated in such a way that a product falls precisely onto a specific metering channel, for example that which is the most empty. The numerical simulation can simulate and validate a plurality of scenarios by the adaptation of the parameter “rotational speed of the distribution plate”. During the performance of the process, changes can also be incorporated into the simulation, such as, for example, if further products are added, further metering channels can empty . . . ), and the control data set can be correspondingly adapted.

Furthermore, for example, a rotational speed of a distribution plate could be controlled in such a way that a plurality of products located on the distribution plate fall into a specific metering channel in order to achieve a filling of all metering channels which is as optimal as possible during the distribution of these products, for example by adaptation and optimization of the parameter rotational speed of the distribution plate. The numerical simulation can simulate and validate a plurality of scenarios for the movement of a plurality of products on the distribution plate, and changes can also be incorporated into the simulation during the performance of the process, for example if further products are added or further metering channels become empty. The control data set can be correspondingly adapted.

A further example of an optimized control with the aid of simulated control parameters is the increase in the vibration amplitude of the metering channel in conjunction with the reduction in the metering time (opening times of the container flaps), owing to changes in the product properties, such as, for example, contamination of the transport paths by abrasion of products, etc. A product behavior can also be simulated if, for example, the scale empties all containers at the same time, which can cause blockages in the further product path (for example collecting funnel). It is also possible to simulate how the stickiness (static friction) of the product influences the lump, such as, for example, an irregular covering of distribution plate and metering channels can occur, which leads to so-called “gaps” or “valleys”. This can lead to overfilling, empty filling, adhesions, clamping of products between the containers, and distortion of the product during falling, which can lead to separation of individual discards of the containers.

The digital model can also be integrated in conjunction with numerical simulations into the complete controller of a system, in order to predict the effects of normal and abnormal operating states, in order to take into account, for example, an increased or else reduced product feed in the case of upstream system parts, the changes in the product properties owing to changes in the product feed, changes in the ventilation concept of the hall in which the machine is standing, temperature changes in the hall, changes in the solar radiation from a certain event, and contamination of product-carrying parts of the scale. Here, for example, a compensation of the changed behavior can be simulated, and certain events can also be incorporated into the simulation, such as, for example, cleaning, pivoting of certain flaps, and/or an increase in the vibration frequencies of the amplitude.

Drafts can arise, for example, as a result of fans, opening/closing of hall doors, passage of large means of transport.

After the simulation, all relevant parameters of the digital model/of the control data set can be stored, for example, in a cloud. In the case of new scales of a similar type or similar products, the simulation can then be started directly with the digital model and the results of the optimized control parameters, and new parameters can be adapted. The parameters can also be newly correlated or corrected on the basis of a wide data situation. A permanent comparison with reality can also always take place via sensors, status messages, error messages, logfiles, and production results, or with the data pool of data of similar scales. Simulation results can thus be validated.

A simulation device according to the invention comprises:
an input device which is adapted to read in a digital model of a basic configuration of the scale, an initial control data set of the scale and data of the products to be transported;
a computing unit which is adapted to simulate the behavior of a product to be transported as a function of the initial control data set with the aid of numerical simulation, and to carry out adaptations and/or optimizations of the control data set of (and optionally of the digital model) of the scale;
an output device which is adapted to output a control data set (and optionally a digital model) (which has/have been adapted and/or optimized).

The above-described advantages can be achieved with such a simulation device.

Further preferably, in the simulation device, the computing unit is adapted to optimize the control data set of the scale and/or optionally the basic configuration of the scale based on simulated product behavior, preferably simulated product speed, simulated homogeneity of the product flow and/or the simulated probability of the occurrence of product jam. A certain data set which can correspondingly evaluate corresponding events is then present in the simulation device.

Furthermore, the input device is preferably adapted to read in the geometric dimensions of the scale or of parts of the scale and/or surface properties of the scale or of parts of the scale. The precise number of parameters can be defined more precisely in this case.

Preferably, the input device is adapted to read in characteristic product properties, preferably geometric dimensions of products and/or surface properties of products and/or friction properties of products.

These properties can be important when it comes to whether products can become wedged, adhere to one another or in another way block a transport path of a scale. Furthermore, the input device is also preferably adapted to read in the environmental properties of the scale, such as, for example, temperature or humidity.

These parameters can also have an influence on the product properties, for example on the behavior of deep-frozen fries or chocolate.

Optionally, the input device is adapted to read in data of the transport path of the scale from the digital model, wherein the transport path contains a charging device and/or a distribution plate and/or at least one metering channel and/or at least one storage container and/or at least one weighing container and/or at least one collecting container and/or at least one chute and/or a funnel and/or a product guiding device and/or stoppers and/or diverter plates. The input device and output device are furthermore adapted to read in or output control parameters of a charging device drive of a charging device, of a distributor plate drive of a distribution plate, of a metering channel drive of a metering channel, preferably the vibration frequency and the vibration amplitude, as a control data set. Initial control data parameters can be input into the input device, and optimized parameters which can subsequently be used in a real scale can be output by the output device on the basis of a simulation and/or optimization.

Preferably, the input device and the output device are adapted to read in or output control parameters of a product guiding device drive of a product guiding device, preferably the movement speed of the product guiding device drive, as a control data set.

Further preferably, the input device and the output device are adapted to read in or output control parameters of at least one storage container flap of a storage container, at least one weighing container flap of a weighing container and/or at least one collecting container flap of a collecting container, preferably the opening time and opening duration, as a control data set. These values can also be read in initially, can then be correspondingly optimized within the scope of the numerical simulation, and therefore these values can be correspondingly optimized with regard to product flow, product movement speed or probability of the occurrence of product jam.

With the method according to the invention and the simulation device according to the invention, there is also the possibility of operating a hybrid operation of the scale. For this purpose, a subregion of the scale is integrated into the real controller as a digital model or as a numerical simulation.

For example, a start-up operation of the real scale takes place during the final acceptance with simulated product behavior: the control parameters can be adapted via the numerical simulation to the product distribution situations to be expected for the product, e.g. the vibration amplitudes of the distribution plate, of the metering channels, the opening times of the containers, and/or drop times. Here, a continuous operation in the quasi-real mode is hence carried out.

The aim can also be pursued of recording initial parameters of the quasi-real operation (initial pattern) at the delivery time, e.g. current forms, times, temperatures, vibrations, acoustics. A later comparison with these allows deviations to be detected, which can be advantageous for monitoring the operating conditions and for planning the maintenance.

This can be followed by a qualification of new assemblies within the scope of a completely simulated remaining scale: e.g. a pivoting funnel unit of a transfer system is loaded with simulated, different products by the digital model of the scale. Fluctuations which occur are then generated by the digital model and the numerical simulation, and the effect on the behavior of the new assembly is tested. Thus, necessary parameters for the operation can be determined, e.g. a dwell time/pivoting time of a pivoting funnel at a predefined output. Problem situations can thus be detected more easily later.

Preferred embodiments of the present invention will now be explained in more detail with reference to the accompanying figures.

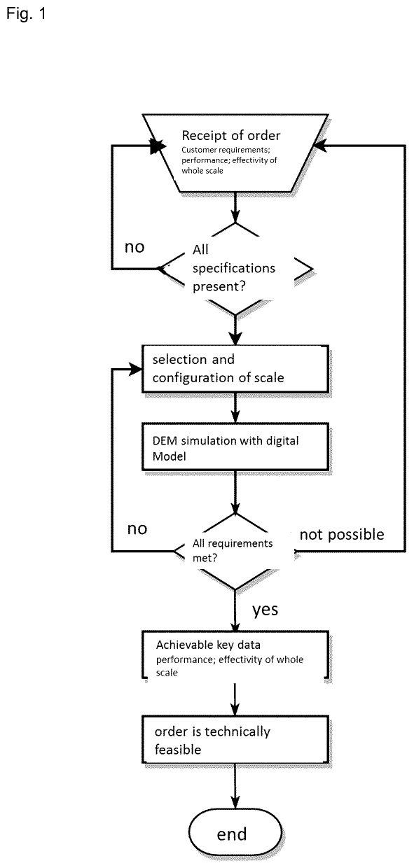

FIG. 1 shows, by way of example, a configuration process of a scale. In a first step, all customer requirements, for example with regard to the desired output of the scale, are checked. If all requirements are present, a basic framework of a specific scale can be selected and configured. A numerical simulation is then carried out using a digital model. If all requirements are met, achievable key data, such as the output, are output, and it can be decided that the job can be carried out technically. If not all requirements are met, it is necessary to improve the selection and configuration of the scale, i.e. only some parts of the scale, and thus also the digital model, have to be changed. If a simulation is not possible, the job cannot be carried out in this way.

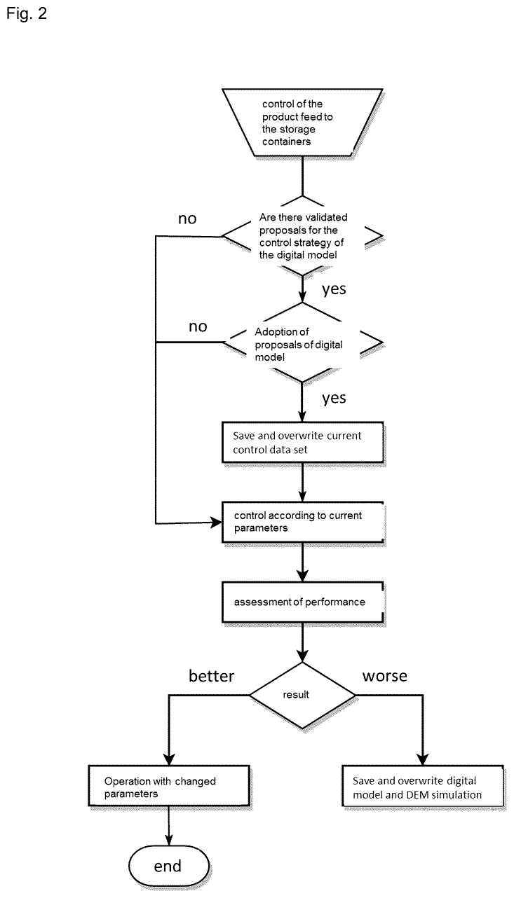

FIG. 2 shows, by way of example, how the control of the product feed to the storage containers can be correspondingly regulated according to the present invention. For this purpose, it is first checked whether there are validated proposals for the control strategy of the digital model. If this is the case, the proposals of the digital model are adopted, corresponding values are then determined by simulation, current parameters are saved and overwritten. If this is not the case, the control has to be carried out according to the current parameters. The corresponding output of the scale then has to be assessed. If the result is better than with the initial control data, the operation is carried out with changed parameters. If the result is worse than the input values, the digital model and the numerical simulation then have to be updated, and the system has to be newly trained.

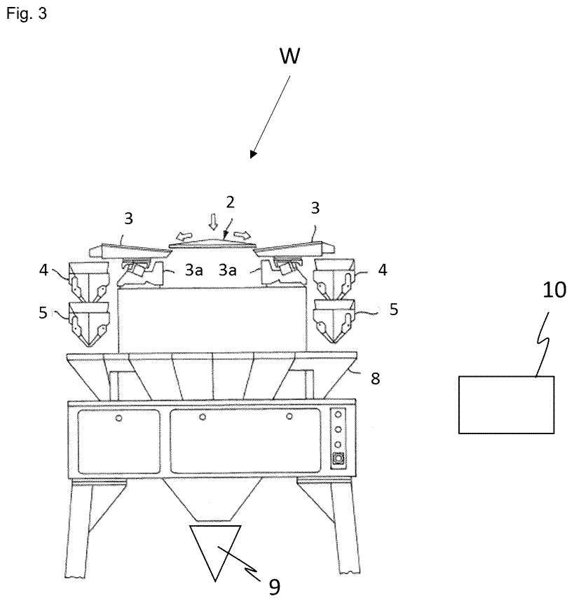

FIG. 3 shows a scale W schematically. Here, a distribution plate 2 can be seen, from which products can fall onto metering channels 3, which are driven in each case by metering channel drives 3a, i.e. are set into vibrations. Products fall from the metering channels 3 into a storage container 4, from which they can fall into a weighing container 5. From there, they are correspondingly collected in a funnel 8, a product guiding device 9 can still correspondingly distribute them after they have left the funnel. A control unit 10 controls the operation of the scale W.

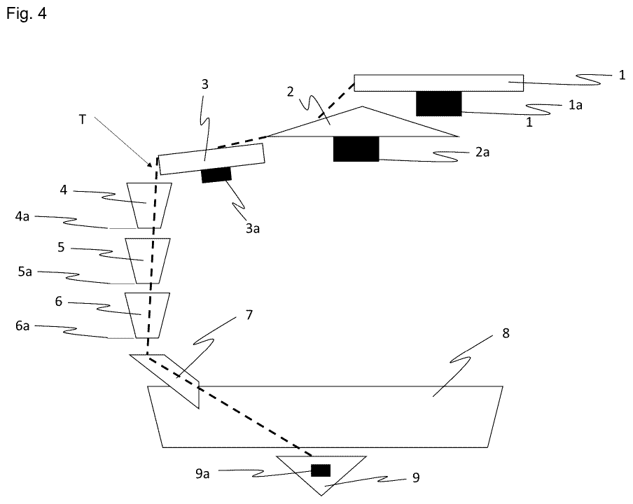

FIG. 4 shows a transport path T over a scale by way of example. In a charging device 1 with a charging device drive 1a, products are conveyed onto a distribution plate 2, which has a distributor plate drive 2a. The distribution plate can either vibrate, or else rotate about its own axis-a combination of both movements is also possible. Products fall from the distribution plate 2 into a metering channel 3, which in turn has a metering channel drive 3a, which can set the metering channel 3 into vibrations. A storage container with storage container flaps 4a, a weighing container 5 with weighing container flaps 5a, and a collecting container with collecting container flaps 6a are arranged below the metering channel 3. A distribution funnel (not shown here) can also be provided between the storage container and the collecting container. Below this, the product can pass into a chute 7, from there into a funnel 8, from where it is fed to a product guiding device 9 with a product guiding device drive 9a, the product guiding device can then distribute the product into corresponding containers. All elements can also be present multiple times, for example 2 distribution plates. The product guiding device 9 can also be a complex transfer system.

Here, it becomes clear that the control data of the charging device drive 1a, of the distributor plate drive 2a, of the metering channel drive 3a, of the storage container flaps 4a, of the weighing container flaps 5a, of the collecting container flaps 6a and of the product guiding device drive 9a can be correspondingly changed. As a result, the movement profile of the products can be correspondingly changed. The parameters can correspondingly be simulated in different combinations, and it can thus be established which is the best control data set which correspondingly leads to the fewest product jams or other disturbances.

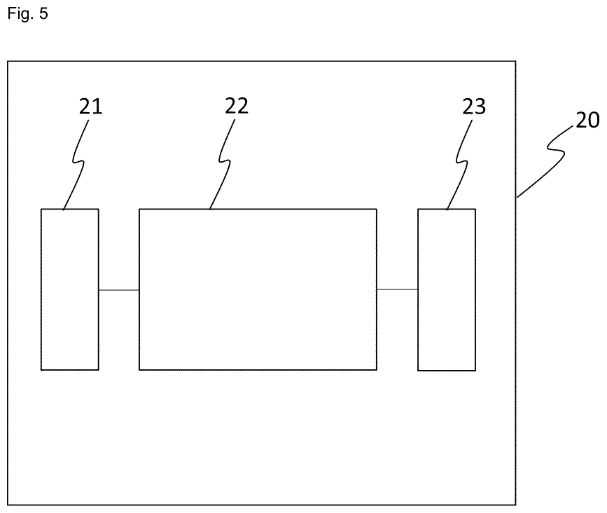

FIG. 5 shows a simulation device 20 schematically. The latter comprises an input device 21, a computing unit 22 and an output device 23.

The present application is not restricted to the above-described embodiments. Further degrees of freedom can also be present in a scale, the geometric dimensions of which and/or the control parameters of which could be correspondingly changed.

The following aspects belong to the disclosure of the present invention.

1. Method for configuring a scale, in particular a combination scale, comprising the following steps:
a) providing a digital model (DM) of a basic configuration of the scale and an initial control data set (SD) of the scale;
b) providing data of the products (P) to be transported;
c) numerical simulation of the movement of products over the transport path (T) of the scale (W);
d) adapting and/or optimizing the digital model (DM) of the scale (W) and/or the control data set (SD) of the scale (W), based on results of the numerical simulation;
e) outputting the digital model (DM) and/or the control data set (SD) of the scale.

2. Method for configuring a scale (W) according to item 1, further comprising the following step:
f) reading the control data set (SD) generated in step e) into a control device of the scale (W).

3. Method according to item 1 or 2, wherein, in step a), the basic configuration of the scale (W) includes the geometric dimensions of the scale (W) or of parts of the scale (W) and/or includes surface properties of the scale (W) or of parts of the scale (W).

4. Method according to one of the items 1 to 3, wherein, in step a), the basic configuration of the scale (W) includes environmental properties of the scale, for example, the temperature and/or the humidity and/or air movements.

5. Method according to one of the preceding items, wherein the transport path (T) of the scale (W) contains at least one charging device (1) and/or at least one distribution plate (2) and/or at least one metering channel (3) and/or at least one storage container (4) and/or at least one weighing container (5) and/or at least one collecting container (6) and/or at least one chute (7) and/or a funnel (8) and/or a product guiding device (9), and optionally also contains the conveying devices connected to the scale.

6. Method according to item 5, wherein a charging device (1) has a charging device drive (1a), a distribution plate (2) has a distribution plate drive (2a), a metering channel (3) has a metering channel drive (3a) and a product guiding device (9) has a product guiding device drive (9a), and/or wherein a storage container (4) has at least one storage container flap (4a), a weighing container (5) has at least one weighing container flap (5a) and a collecting container (6) has at least one collecting container flap (6a).

7. Method according to item 6, wherein the transport path (T) of the scale (W) further comprises stoppers and/or diverter plates.

8. Method according to one of the preceding items, wherein, in step c) and/or d), bore tolerances, length tolerances and/or position tolerances are taken into account in the simulation.

9. Method according to one of the preceding items, wherein, in step b), characteristic product properties, preferably geometric dimensions, weights, of products (P) and/or surface properties of products (P) and/or friction properties of products (P) are provided.

10. Method according to one of the preceding items, wherein, in step d), the basic configuration of the scale (W) and/or the control data set (SD) of the scale are optimized based on simulated product behavior, preferably simulated product speed, simulated homogeneity of the product flow and/or the simulated probability of the occurrence of product jam.

11. Method according to one of the preceding items 6 to 10, wherein the control data set (SD) of the scale contains at least one of the following parameters:
vibration amplitude of the distributor plate drive (2a),
vibration frequency of the distributor plate drive (2a),
rotational speed profile of the distributor plate drive (2a),
vibration amplitude of at least one metering channel drive (3a),
vibration frequency of at least one metering channel drive (3a),
opening time and opening duration of the at least one storage container flap (4a),
opening time and opening duration of the at least one weighing container flap (5a),
opening time and opening duration of the at least one collecting container flap (6a),
movement sequences of a product guiding device (9).

12. Method according to one of the preceding items, wherein, in step c), N products (P) are used for the simulation.

13. Simulation device (20) for the operation of a scale, in particular a combination scale, comprising:
an input device (21) which is adapted to read in a digital model (DM) of a basic configuration of the scale, an initial control data set (SD) of the scale and data of the products (P) to be transported;
a computing unit (22) which is adapted to simulate the behavior of a product (P) to be transported as a function of the initial control data set (SD) with the aid of numerical simulation, and to carry out adaptations and/or optimizations of the basic configuration of the scale (W) and/or the control data set (SD) of the scale;
an output device (23) which is adapted to output an optimized digital model and/or an optimized control data set (SD).

14. Simulation device (20) according to item 13, wherein the computing unit (22) is adapted to optimize the digital model (DM) of the scale (W) and/or the control data set (SD) of the scale based on simulated product behavior, preferably simulated product speed, simulated homogeneity of the product flow and/or the simulated probability of the occurrence of product jam.

15. Simulation device (20) according to item 13 or 14, wherein the input device (21) is adapted to read in the geometric dimensions of the scale (W) or of parts of the scale (W) and/or surface properties of the scale (W) or of parts of the scale (W).

16. Simulation device (20) according to one of the items 13 to 15, wherein the input device (21) is adapted to read in characteristic product properties, preferably geometric dimensions, weights, of products (P) and/or surface properties of products (P) and/or friction properties of products (P).

17. Simulation device (20) according to one of the items 13 to 16, wherein the input device (21) is adapted to read in the environmental properties of the scale, for example, the temperature and/or the humidity and/or the air movement.

18. Simulation device (20) according to one of the items 13 to 17, wherein the input device (21) is adapted to read in data of the transport path (T) of the scale (W) as a digital model (DM), wherein the transport path (T) contains a charging device (1) and/or a distribution plate (2) and/or at least one metering channel (3) and/or at least one storage container (4) and/or at least one weighing container (5) and/or at least one collecting container (6) and/or at least one chute (7) and/or a funnel (8) and/or a product guiding device (9) and/or stoppers and/or diverter plates, and optionally also contains conveying devices connected to the scale.

19. Simulation device (20) according to one of the items 13 to 18, wherein the input device (21) and the output device (23) are adapted to read in or output control parameters of a charging device drive (1a) of a charging device (1), of a distributor plate drive (2a) of a distribution plate (2), of a metering channel drive (3a) of a metering channel (3), as a control data set (SD), preferably the vibration frequency and the vibration amplitude.

20. Simulation device (20) according to one of the items 13 to 19, wherein the input device (21) and the output device (23) are adapted to read in or output control parameters of a product guiding device drive (9a) of a product guiding device (9), preferably the movement speed of the product guiding device drive (9a), as a control data set (SD).

21. Simulation device (20) according to one of the items 13 to 20, wherein the input device (21) and the output device (23) are adapted to read in or output control parameters of at least one storage container flap (4a) of a storage container (4), at least one weighing container flap (5a) of a weighing container (5) and/or at least one collecting container flap (6a) of a collecting container (6), preferably the opening time and opening duration, as a control data set (SD).

### REFERENCE CHARACTERS LIST

W Scale
DM Digital model
SD control data set
P product
T Transport path
1 Charging device
1a Charging device drive
2 Distribution plate
2a Distributor plate drive
3 Metering channel
3a Metering channel drive
4 Storage container
4a Storage container flaps
5 Weighing container
5a Weighing container flaps
6 Collecting container
6a Collecting container flaps
7 chute
8 funnel
9 product guiding device
9a product guiding device drive
10 control device
20 simulation device
21 input device
22 computing unit
23 output device

Although the invention has been described in detail with reference to certain preferred embodiments, variations and modifications exist within the scope and spirit of one or more independent aspects of the invention as described.

What is claimed is:

1. A method for configuring a scale (W), in particular a combination scale, comprising the following steps:
a) providing a digital model (DM) of a basic configuration of the scale and an initial control data set (SD) of the scale;
b) providing data of the products (P) to be transported;
c) numerical simulation of the movement of products over the transport path (T) of the scale (W);
d) adapting and/or optimizing the control data set (SD) of the scale (W), based on results of the numerical simulation;
e) outputting the adapted and/or optimized control data set (SD) of the scale.

2. The method for configuring a scale (W) according to claim 1, further comprising the following step:
f) reading the control data set (SD) generated in step e) into a control device of the scale (W).

3. The method according to claim 1, wherein the transport path (T) of the scale (W) contains a charging device (1) and/or a distribution plate (2) and/or at least one metering channel (3) and/or at least one storage container (4) and/or at least one weighing container (5) and/or at least one collecting container (6) and/or at least one chute (7) and/or a funnel (8) and/or a product guiding device (9), and optionally also contains the conveying devices connected to the scale, wherein the transport path optionally further comprises stoppers and/or diverter plates.

4. The method according to claim 3, wherein a charging device (1) has a charging device drive (1a), a distribution plate (2) has a distribution plate drive (2a), a metering channel (3) has a metering channel drive (3a) and a product guiding device (9) has a product guiding device drive (9a), and/or wherein a storage container (4) has at least one storage container flap (4a), a weighing container (5) has at least one weighing container flap (5a) and a collecting container (6) has at least one collecting container flap (6a).

5. The method according to claim 1, wherein in step b), characteristic product properties, preferably geometric dimensions, weights, of products (P) and/or surface properties of products (P) and/or friction properties of products (P) are provided.

6. The method according to claim 1, wherein in step d), the control data set (SD) of the scale and/or the basic configuration of the scale (W) is/are optimized based on simulated product behavior, preferably simulated product speed, simulated homogeneity of the product flow and/or the simulated probability of the occurrence of product jam.

7. The method according to claim 3, wherein the control data set (SD) of the scale contains at least one of the following parameters:
vibration amplitude of the distributor plate drive (2a),
vibration frequency of the distributor plate drive (2a),
rotational speed profile of the distributor plate drive (2a),
vibration amplitude of at least one metering channel drive (3a),
vibration frequency of at least one metering channel drive (3a),
opening time and opening duration of the at least one storage container flap (4a),
opening time and opening duration of the at least one weighing container flap (5a),
opening time and opening duration of the at least one collecting container flap (6a), and/or
movement sequences of a product guiding device (9).

8. The method according to claim 1, wherein, in step c), N products (P) are used for the simulation.

9. A simulation device (20) for the operation of a scale, in particular a combination scale, comprising:
an input device (21) which is adapted to read in a digital model (DM) of a basic configuration of the scale, an initial control data set (SD) of the scale and data of the products (P) to be transported;
a computing unit (22) which is adapted to simulate the behavior of a product (P) to be transported as a function of the initial control data set (SD) with the aid of numerical simulation, and to carry out adaptations and/or optimizations of the control data set (SD) of the scale (W);
an output device (23) which is adapted to output an adapted and/or optimized control data set (SD).

10. The simulation device (20) according to claim 9, wherein the computing unit (22) is adapted to optimize the control data set (SD) of the scale based on simulated product behavior, preferably simulated product speed, simulated homogeneity of the product flow and/or the simulated probability of the occurrence of product jam.

11. The simulation device (20) according to claim 9, wherein the input device (21) is adapted to read in characteristic product properties, preferably geometric dimensions, weights, of products (P) and/or surface properties of products (P) and/or friction properties of products (P).

12. The simulation device (20) according to claim 9, wherein the input device (21) is adapted to read in data of the transport path (T) of the scale (W) as a digital model (DM), wherein the transport path (T) contains a charging device (1) and/or a distribution plate (2) and/or at least one metering channel (3) and/or at least one storage container (4) and/or at least one weighing container (5) and/or at least one collecting container (6) and/or at least one chute (7) and/or a funnel (8) and/or a product guiding device (9) and/or stoppers and/or diverter plates, and optionally also contains conveying devices connected to the scale.

13. The simulation device (20) according to claim 9, wherein the input device (21) and the output device (23) are adapted to read in or output control parameters of a charging device drive (1a) of a charging device (1), of a distributor plate drive (2a) of a distribution plate (2), of a metering channel drive (3a) of a metering channel (3), as a control data set (SD), preferably the vibration frequency and the vibration amplitude.

14. The simulation device (20) according to claim 9, wherein the input device (21) as well as the output device (23) are adapted to read in or output as control data set (SD) control parameters of a product guiding device drive (9a) of a product guiding device (9), preferably the speed of movement of the product guiding device drive (9a).

15. The simulation device (20) according to claim 9, wherein the input device (21) as well as the output device (23) are adapted to read in or output as control data set (SD) control parameters of at least one storage container flap (4a) of a storage container (4), at least one weighing container flap (5a) of a weighing container (5) and/or at least one collecting container flap (6a) of a collecting container (6), preferably the opening time and opening duration.
